(19) United States
(12) Patent Application Publication
(10) Pub. No.: US 2023/0108181 A1
(43) Pub. Date: Apr. 6, 2023

(54) Segmented Leadframe for Flip Chip Attaching a Semiconductor Die Including Prevention of Die Tilt

(71) Applicant: Infineon Technologies AG, Neubiberg (DE)

(72) Inventors: Michael Stadler, Muenchen (DE); Milad Mostofizadeh, Muenchen (DE)

(21) Appl. No.: 17/959,583

(22) Filed: Oct. 4, 2022

(30) Foreign Application Priority Data
Oct. 5, 2021 (DE) 102021125780.8

(51) Int. Cl. H01L 23/495; H01L 23/00

(52) U.S. Cl. CPC H01L 23/49513; H01L 23/49562; H01L 24/32; H01L 24/29; H01L 24/40; H01L 24/73; H01L 2224/32245; H01L 2224/291; H01L 2224/40245; H01L 2224/73263

(57) ABSTRACT

A leadframe for flip chip attaching a semiconductor die thereon includes a rectangular area segmented into individual pads, the individual pads including a first pad, a second pad, and a third pad, wherein the first pad is larger than the second pad and larger than the third pad, and the second pad is located in a first corner area of the rectangular area and the third pad is located in a second corner area of the rectangular area, the second corner area being located diagonally opposite to the first corner area.

### TECHNICAL FIELD

The present disclosure is related to a leadframe for flip chip attaching a semiconductor die and a flip chip semiconductor package comprising such a leadframe.

### BACKGROUND

Flip chip die attach is a method for making electrical connections to a chip, where the chip is inverted and its bond pads are connected to a corresponding pattern of bond pads on a substrate. Flip chip assembly is an alternative to the chip and wire assembly technique and is most commonly used where space is an issue, where there are a high number of chip connections, where good high frequency performance is required, or a combination of these factors.

For flip die attachment, the gate pad forms a singularized part of the leadframe. There will be a gap between the source pad and the gate pad. The lack of solder at this gap will form a non-symmetric pressure distribution leading to a systematic die tilt. The pressure in the liquid solder is distributed unevenly at the chip. Therefore, the chip is tilting down at the gate pad. This leads to a systematic low bond layer thickness (BLT) at the gate pad, which in turn may lead to solder joint fracture at this location. This can be countered by using more solder material to increase the BLT which, however, does not resolve the die tilt issue.

### SUMMARY

A first aspect of the present disclosure is related to a leadframe for flip chip attaching a semiconductor die thereon, the leadframe comprising a rectangular area segmented into individual pads, the individual pads comprising a first pad, a second pad, and a third pad, wherein the first pad is larger than the second pad and larger than the third pad, and the second pad is located in a first corner area of the rectangular area and the third pad is located in a second corner area of the rectangular area, the second corner area being located diagonally opposite to the first corner area.

A second aspect of the present disclosure is related to a flip chip semiconductor package, comprising a leadframe comprising a rectangular area segmented into individual pads, the individual pads comprising a first pad, a second pad, and a third pad, wherein the first pad is larger than the second pad and larger than the third pad, and the second pad is located in a first corner area of the rectangular area and the third pad is located in a second corner area of the rectangular area, the second corner area being located diagonally opposite to the first corner area, and a semiconductor die comprising a first electrode and a second electrode, the semiconductor die being attached to the leadframe with the first electrode being connected with the first pad and the third pad, and the second electrode being connected with the second pad.

The present disclosure according to the above first and second aspects will lead to a systematic reduction of the semiconductor die tilt. Another advantage of the present disclosure is an improvement of the outgassing of voids contained in the solder material.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description.

The elements of the drawings are not necessarily to scale relative to each other. Like reference numerals designate corresponding similar parts.

FIG. 1 comprises FIG. 1A and 1B and shows an example of a leadframe according to the first aspect in a top view (A) and in a perspective view (B).

FIG. 2 shows an example of a flip chip semiconductor package according to the second aspect in an explosion view.

### DESCRIPTION OF EMBODIMENTS

In the following detailed description, reference is made to the accompanying drawings, which form a part hereof, and in which is shown by way of illustration specific embodiments in which the disclosure may be practiced. In this regard, directional terminology, such as “top”, “bottom”, “front”, “back”, etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present disclosure. The following detailed description, therefore, is not to be taken in a limiting sense, and the scope of the present disclosure is defined by the appended claims.

It is to be understood that the features of the various exemplary embodiments described herein may be combined with each other, unless specifically noted otherwise.

As employed in this specification, the terms “bonded”, “attached”, “connected”, “coupled” and/or “electrically connected/electrically coupled” are not meant to mean that the elements or layers must directly be contacted together; intervening elements or layers may be provided between the “bonded”, “attached”, “connected”, “coupled” and/or “electrically connected/electrically coupled” elements, respectively. However, in accordance with the disclosure, the above-mentioned terms may, optionally, also have the specific meaning that the elements or layers are directly contacted together, i.e. that no intervening elements or layers are provided between the “bonded”, “attached”, “connected”, “coupled” and/or “electrically connected/electrically coupled” elements, respectively.

Further, the word “over” used with regard to a part, element or material layer formed or located “over” a surface may be used herein to mean that the part, element or material layer be located (e.g. placed, formed, deposited, etc.) “indirectly on” the implied surface with one or more additional parts, elements or layers being arranged between the implied surface and the part, element or material layer. However, the word “over” used with regard to a part, element or material layer formed or located “over” a surface may, optionally, also have the specific meaning that the part, element or material layer be located (e.g. placed, formed, deposited, etc.) “directly on”, e.g. in direct contact with, the implied surface.

### DETAILED DESCRIPTION

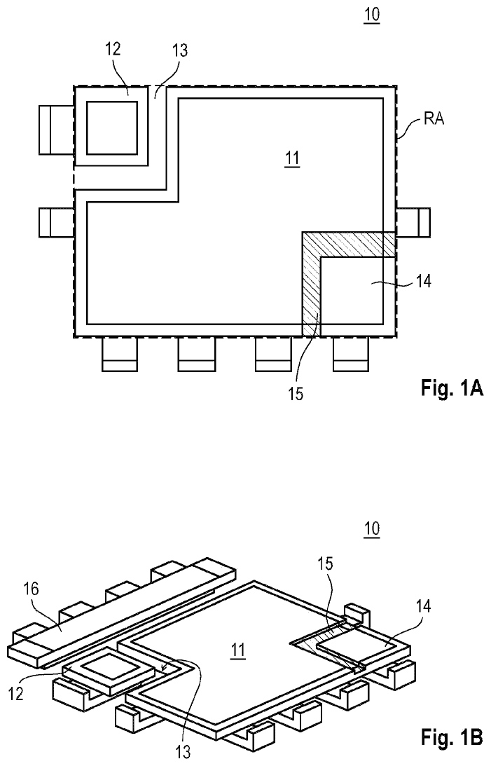

FIG. 1 comprises FIG. 1A and 1B and shows an example of a leadframe according to the first aspect in a top view (A) and in a perspective view (B).

In particular, FIG. 1 shows a leadframe 10 for flip chip attaching a semiconductor die thereon. The leadframe 10 comprises a rectangular area RA which is marked by a dashed line and segmented into individual pads, wherein the individual pads comprise a first pad 11, a second pad 12, and a third pad 14, wherein the first pad 11 is larger than the second pad 12 and larger than the third pad 14.

As can be seen in FIG. 1, the second pad 12 is located in a first upper left corner area of the rectangular area RA and the third pad 14 is located in a second lower right corner area of the rectangular area RA, wherein the second corner area is located diagonally opposite to the first corner area.

The semiconductor die to be attached to the leadframe can be a semiconductor transistor die comprising a first electrode and a second electrode, wherein the first electrode is the source electrode and the second electrode is the gate electrode. The source electrode is to be connected with the first pad 11 of the leadframe 10 and the gate electrode is to be connected with the second pad 12 of the leadframe 10.

As can also be seen in FIG. 1, a gap 13 is disposed between the first pad 11 and the second pad 12 and a recess 15 is located between the first pad 11 and the third pad 14, the recess 15 being formed into a common metallic area of the first pad 11 and the third pad 14. The recess 15 may comprise a depth in a range of 30% to 70% of the thickness of the first pad 11, in particular a depth around 50% of the thickness of the first pad 11, a so-called half-cut.

The first pad 11 and the third pad 14 are thus electrically connected with each other and are lying on one and the same electric potential. It should be added, however, that this is not necessarily the case. It is also possible to replace the recess 15 by a gap so that there is no more any electrical connection between the first pad 11 and the third pad 14.

Same as with the relationship between the second pad 12 and the third pad 14, also the gap 13 and the recess 15 can be arranged diagonally opposite to each other.

The embodiment as shown in FIG. 1 is furthermore so that the second pad 12 and the third pad 14 have equal sizes and exactly the same quadratic shape and are positioned in a point-symmetric arrangement with respect to each other. It should be mentioned, however, that also this is not necessarily the case. The shapes of the second pad 12 and the third pad 14 need not be quadratic and, moreover, can deviate from each other and need not necessarily be arranged point-symmetrically to each other.

A result of the above described arrangement is a significant reduction of the tilt of the semiconductor die when attaching the semiconductor die by means of solder material to the leadframe 10 caused by symmetric pressure distribution during the attachment process. A further advantage of the above described arrangement is an improvement of the escape of voids contained in the solder material. These voids can escape by moving along the recess 15 and crossing the two transitions from the recess 15 to the outside environment.

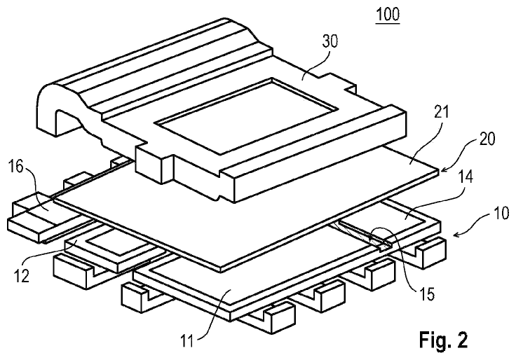

FIG. 2 shows an example of a flip chip semiconductor package according to the second aspect in an explosion view.

The flip chip semiconductor package 100 may comprise a leadframe 10 such as that shown and described above in connection with FIG. 1. The flip chip semiconductor package 100 may further comprise a semiconductor die 20 comprising a first electrode and a second electrode (both not to be seen in FIG. 2), the semiconductor die 20 being attached to the leadframe 10 with the first electrode being connected with the first pad 11 and the third pad 14, and the second electrode being connected with the second pad 12.

In the flip chip semiconductor package 100 the semiconductor die 20 to be attached to the leadframe 10 can be a semiconductor transistor die 20 comprising a first electrode and a second electrode (both not to be seen in FIG. 2), wherein the first electrode is the source electrode and the second electrode is the gate electrode. The source electrode is to be connected with the first pad 11 of the leadframe 10 and the gate electrode is to be connected with the second pad 12 of the leadframe 10.

The flip chip semiconductor package 100 may further comprise a solder layer (not to be seen in FIG. 2) disposed between the first electrode and the first pad 11 and the third pad 14. According to a further example thereof, a part of the solder layer is filled into the recess 15 while not completely filling the recess.

In the flip chip semiconductor package 13 the leadframe may further comprise a drain pad 16, and the semiconductor transistor die 20 may further comprise a drain electrode 21, the drain electrode 21 being connected with the drain pad 16 by a clip 30. In other embodiments, the drain pad 16 is not necessary. For example, the leads for drain electrode 21 can be made by the clip 30 itself, or the drain electrode 21 can be directly exposed from the top surface of the package, i.e., top side cooling package. In these embodiments, the lead frame 10 does not have the drain leads/pad 16.

### EXAMPLES

In the following specific examples of the present disclosure are described.

Example 1 is a leadframe for flip chip attaching a semiconductor die thereon, the leadframe comprising a rectangular area segmented into individual pads, the individual pads comprising a first pad, a second pad, and a third pad, wherein the first pad is larger than the second pad and larger than the third pad, and the second pad is located in a first corner area of the rectangular area and the third pad is located in a second corner area of the rectangular area, the second corner area being located diagonally opposite to the first corner area.

Example 2 is the leadframe according to Example 1, further comprising a gap disposed between the first pad and the second pad, and a recess located between the first pad and the third pad, the recess being formed into a common metallic area of the first pad and the third pad.

Example 3 is the leadframe according to Example 2, wherein the gap and the recess are arranged diagonally opposite to each other.

Example 4 is the leadframe according to Example 2 or 3, wherein the recess comprises a depth in a range of 30% to 70% of the thickness of the first pad.

Example 5 is the leadframe according to any one of the preceding Examples, wherein the semiconductor die is a semiconductor transistor die, the first pad is the source pad and the second pad is the gate pad.

Example 6 is a flip chip semiconductor package, comprising a leadframe comprising a rectangular area segmented into individual pads, the individual pads comprising a first pad, a second pad, and a third pad, wherein the first pad is larger than the second pad and larger than the third pad, and the second pad is located in a first corner area of the rectangular area and the third pad is located in a second corner area of the rectangular area, the second corner area being located diagonally opposite to the first corner area; and a semiconductor die comprising a first electrode and a second electrode, the semiconductor die being attached to the leadframe with the first electrode being connected with the first pad and the third pad, and the second electrode being connected with the second pad.

Example 7 is the flip chip semiconductor package according to Example 6, wherein the leadframe further comprises a gap disposed between the first pad and the second pad, and a recess located between the first pad and the third pad, the recess being formed into a common metallic area of the first pad and the third pad (14).

Example 8 is the flip chip semiconductor package according to Example 7, further comprising a solder layer disposed between the first electrode and the first pad and the third pad.

Example 9 is the flip chip semiconductor package according to Example 8, wherein a part of the solder layer is filled into the recess while not completely filling the recess.

Example 10 is the flip chip semiconductor package according to Example 8 or 9, wherein the gap and the recess are arranged diagonally opposite to each other.

Example 11 is the flip chip semiconductor package according to any one of Examples 8 to 10, wherein the recess comprises a depth in a range of 30% to 70% of the thickness of the source pad.

Example 12 is the flip chip semiconductor package according to any one of Examples 6 to 11, wherein the semiconductor die is a semiconductor transistor die, the first pad is the source pad and the second pad is the gate pad, the first electrode is the source and the second electrode is the gate electrode.

Example 13 is the flip chip semiconductor package according to Example 12, wherein the leadframe further comprises a drain pad, and the semiconductor transistor die further comprises a drain electrode, the drain electrode being connected with the drain pad by a clip.

In addition, while a particular feature or aspect of an embodiment of the disclosure may have been disclosed with respect to only one of several implementations, such feature or aspect may be combined with one or more other features or aspects of the other implementations as may be desired and advantageous for any given or particular application. Furthermore, to the extent that the terms “include”, “have”, “with”, or other variants thereof are used in either the detailed description or the claims, such terms are intended to be inclusive in a manner similar to the term “comprise”. Furthermore, it should be understood that embodiments of the disclosure may be implemented in discrete circuits, partially integrated circuits or fully integrated circuits or programming means. Also, the term “exemplary” is merely meant as an example, rather than the best or optimal. It is also to be appreciated that features and/or elements depicted herein are illustrated with particular dimensions relative to one another for purposes of simplicity and ease of understanding, and that actual dimensions may differ substantially from that illustrated herein.

Although specific embodiments have been illustrated and described herein, it will be appreciated by those of ordinary skill in the art that a variety of alternate and/or equivalent implementations may be substituted for the specific embodiments shown and described without departing from the scope of the present disclosure. This application is intended to cover any adaptations or variations of the specific embodiments discussed herein. Therefore, it is intended that this disclosure be limited only by the claims and the equivalents thereof.

1. A leadframe for flip chip attaching a semiconductor die thereon, the leadframe comprising:
a rectangular area segmented into individual pads,
the individual pads comprising a first pad, a second pad, and a third pad, wherein
the first pad is larger than the second pad and larger than the third pad, and
the second pad is located in a first corner area of the rectangular area and the third pad is located in a second corner area of the rectangular area, the second corner area being located diagonally opposite to the first corner area.

2. The leadframe according to claim 1, further comprising
a gap disposed between the first pad and the second pad, and
a recess located between the first pad and the third pad, the recess being formed into a common metallic area of the first pad and the third pad.

3. The leadframe according to claim 2, wherein the gap and the recess are arranged diagonally opposite to each other.

4. The leadframe according to claim 2, wherein the recess comprises a depth in a range of 30% to 70% of the thickness of the first pad.

5. The leadframe according to claim 1, wherein the semiconductor die is a semiconductor transistor die, the first pad is the source pad and the second pad is the gate pad.

6. A flip chip semiconductor package, comprising
a leadframe comprising a rectangular area segmented into individual pads, the individual pads comprising a first pad, a second pad, and a third pad, wherein the first pad is larger than the second pad and larger than the third pad, and the second pad is located in a first corner area of the rectangular area and the third pad is located in a second corner area of the rectangular area, the second corner area being located diagonally opposite to the first corner area; and
a semiconductor die comprising a first electrode and a second electrode, the semiconductor die being attached to the leadframe with the first electrode being connected with the first pad and the third pad, and the second electrode being connected with the second pad.

7. The flip chip semiconductor package according to claim 6, wherein the leadframe further comprises a gap disposed between the first pad and the second pad, and a recess located between the first pad and the third pad, the recess being formed into a common metallic area of the first pad and the third pad.

8. The flip chip semiconductor package according to claim 7, further comprising
a solder layer disposed between the first electrode and the first pad and the third pad.

9. The flip chip semiconductor package according to claim 8, wherein a part of the solder layer is filled into the recess while not completely filling the recess.

10. The flip chip semiconductor package according to claim 8, wherein the gap and the recess are arranged diagonally opposite to each other.

11. The flip chip semiconductor package according to any one of claims 8, wherein the recess comprises a depth in a range of 30% to 70% of the thickness of the source pad.

12. The flip chip semiconductor package according to claim 6, wherein the semiconductor die is a semiconductor transistor die, the first pad is the source pad and the second pad is the gate pad, the first electrode is the source and the second electrode is the gate electrode.

13. The flip chip semiconductor package according to claim 12, wherein the leadframe further comprises a drain pad, and the semiconductor transistor die further comprises a drain electrode, the drain electrode being connected with the drain pad by a clip.
